(19) United States
(12) Patent Application Publication
(10) Pub. No.: US 2025/0191907 A1
(43) Pub. Date: Jun. 12, 2025

(54) FILM FORMING METHOD AND FILM FORMING APPARATUS

(71) Applicant: Tokyo Electron Limited, Tokyo (JP)

(72) Inventors: Ayuta SUZUKI, Albany, NY (US); Shuji AZUMO, Nirasaki City (JP); Takashi MATSUMOTO, Nirasaki City (JP); Ryota IFUKU, Nirasaki City (JP); Takashi FUSE, Nirasaki City (JP); Toru USUKI, Nirasaki City (JP); Masahito SUGIURA, Nirasaki City (JP)

(21) Appl. No.: 19/042,169

(22) Filed: Jan. 31, 2025

Related U.S. Application Data
(63) Continuation of application No. PCT/JP2023/026200, filed on Jul. 18, 2023.

(30) Foreign Application Priority Data
Aug. 1, 2022 (JP) 2022-122440

(51) Int. Cl. H01L 21/02; C23C 16/52; H01L 21/311

(52) U.S. Cl. CPC H01L 21/02164; C23C 16/52; H01L 21/02115; H01L 21/02274; H01L 21/0228; H01L 21/0234; H01L 21/31116

(57) ABSTRACT

A film forming method includes: preparing a substrate including a first film having a first surface and a second film having a second surface, the second film being different from the first film; selectively forming a graphene-containing film on the second surface; performing hydrogen-containing plasma processing on the substrate after forming the graphene-containing film; and selectively forming a target film on the first surface.

### CROSS-REFERENCE TO RELATED APPLICATION

The application is a Bypass Continuation Application of PCT International Application No. PCT/JP2023/026200, filed on Jul. 18, 2023 and designating the United States, the international application being based upon and claiming the benefit of priority from Japanese Patent Application No. 2022-122440, filed on Aug. 1, 2022, the entire content of which is incorporated herein by reference.

### TECHNICAL FIELD

The present disclosure relates to a film forming method and a film forming apparatus.

### BACKGROUND

Recently, with the progress of miniaturization of semiconductor devices, a technique capable of achieving selective film formation with higher precision than a photolithography technique has been considered. As such a technique, a technique has been proposed in which a self-assembled monolayer (SAM) as a film formation inhibitor is formed on a surface of a substrate region where film formation is not desired, and a target film is formed only on a region of a substrate surface where the SAM is not formed (see e.g., Patent Documents 1 and 2, and Non-Patent Document 1).

On the other hand, a technique in which graphene is used as a material that inhibits formation of a target film on a metal surface has also been proposed (Patent Documents 3 and 4).

### PRIOR ART DOCUMENTS

### Patent Documents

Patent Document 1: Japanese Patent Laid-open Publication No. 2010-540773

Patent Document 2: Japanese Patent Laid-open Publication No. 2013-520028

Patent Document 3: Japanese Patent Laid-open Publication No. 2018-182328

Patent Document 4: U.S. Patent Application Laid-open Publication No. 2022/0068704

### Non-Patent Document

Non-Patent Document 1: Hashemi, F.S.M. et.al. ACS Appl. Mater. Interfaces 2016, 8(48), pp. 33264-33272, Nov. 7, 2016

### SUMMARY

According to one embodiment of the present disclosure, a film forming method includes: preparing a substrate including a first film having a first surface and a second film having a second surface, the second film being different from the first film; selectively forming a graphene-containing film on the second surface; performing hydrogen-containing plasma processing on the substrate after forming the graphene-containing film; and selectively forming a target film on the first surface.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method according to a first embodiment.

FIGS. 2A to 2E are cross-sectional views illustrating each process of the film forming method according to the first embodiment.

FIG. 3 is a flowchart illustrating a film forming method according to a second embodiment.

FIGS. 4A and 4B are cross-sectional views illustrating a part of processes of the film forming method according to the second embodiment.

FIG. 5 is a flowchart illustrating a film forming method according to a third embodiment.

FIG. 6 is a cross-sectional view illustrating a part of processes of the film forming method according to the third embodiment.

FIG. 7 is a schematic diagram illustrating an overall configuration of an example of a film forming apparatus capable of implementing the film forming method according to the first embodiment.

FIG. 8 is a cross-sectional view illustrating an example of a graphene-containing film formation module mounted in the film forming apparatus of FIG. 7.

FIG. 9 is a cross-sectional view schematically illustrating a microwave radiation mechanism in the graphene-containing film formation module of FIG. 8.

FIG. 10 is a bottom view schematically illustrating a ceiling wall of a processing container in the graphene-containing film formation module of FIG. 8.

FIG. 11 is a cross-sectional view illustrating an example of a hydrogen-containing plasma processing module mounted in the film forming apparatus of FIG. 7.

FIG. 12 is a cross-sectional view illustrating an example of a target film formation module mounted in the film forming apparatus of FIG. 7.

FIG. 13 is a diagram illustrating results of measuring contact angles of surfaces before and after a film formation flow of a SiO₂ film with respect to samples 1 to 4 of an experimental example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

First, a first embodiment will be described.

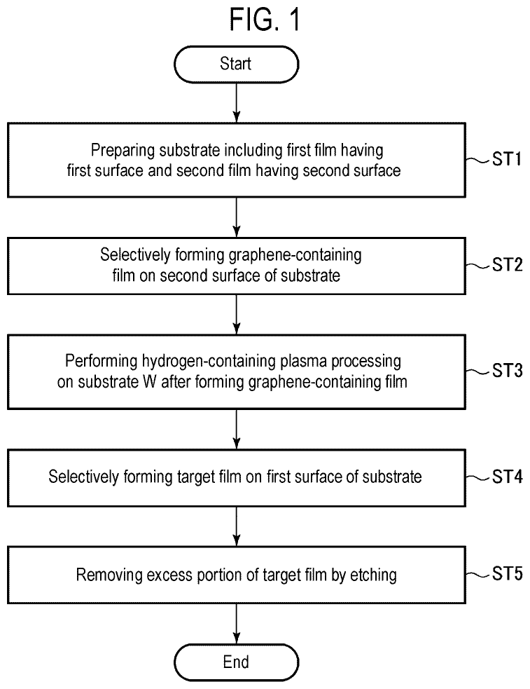

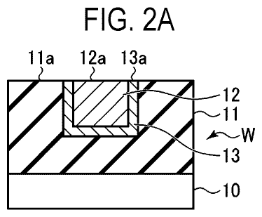

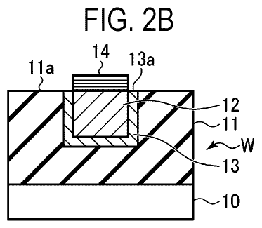

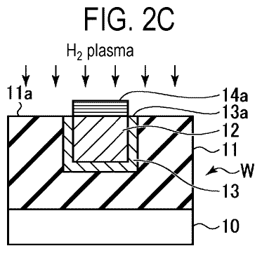

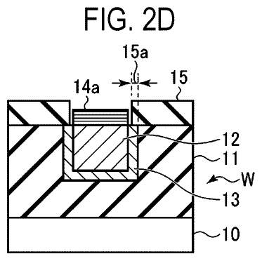

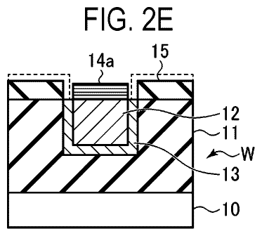

FIG. 1 is a flowchart illustrating a film forming method according to the first embodiment, and FIGS. 2A to 2E are cross-sectional views illustrating each process of the film forming method according to the first embodiment.

First, as illustrated in FIG. 2A, a substrate W, which includes a first film 11 having a first surface 11a and a second film 12 having a second surface 12a, is prepared (step ST1). The second film 12 is different from the first film 11.

The first film 11 is formed on a base 10 and is, for example, an insulating film (dielectric film). When the first film 11 is the insulating film, a conductive film may be formed between the base 10 and the first film 11. The insulating film constituting the first film 11 may be an interlayer insulating film. As the interlayer insulating film, a low dielectric constant (low-k) film is appropriate.

The insulating film constituting the first film 11 is not particularly limited but may be, for example, a SiO₂ film, a SiN film, a SiOC film, a SiON film, or a SiOCN film.

A recess such as a trench or a hole is formed in the first film 11, and the second film 12 is embedded in the recess. The second film 12 is, for example, a conductive film such as a metal film. The conductive film (metal film) constituting the second film 12 is not particularly limited but may be, for example, a Cu film, a Co film, a Ru film, a W film, or a Mo film.

Combinations of the first film 11 and the second film 12 may be arbitrary. For example, a combination of the SiO₂ film as the first film 11 and the Ru film as the second film 12 may be used.

As the substrate W, for example, a semiconductor wafer having the base 10 made of silicon or a compound semiconductor may be used. The compound semiconductor may be, for example, GaAs, SiC, GaN, or InP.

A barrier film 13 may be provided between the first film 11 and the second film 12. When the first film 11 is the insulating film and the second film 12 is the metal film, the barrier film 13 has a function of suppressing diffusion of a metal from the metal film to the insulating film. The barrier film 13 is not particularly limited but may be, for example, a TaN film or a TiN film.

When the substrate W has the barrier film 13, the barrier film 13 has a third surface 13a formed between the first surface 11a and the second surface 12a.

The substrate W is not limited to the structure illustrated in FIG. 2A as long as the substrate W has a first film having an exposed first surface and a second film having an exposed second surface.

Subsequently, as illustrated in FIG. 2B, a graphene-containing film 14 is selectively formed on the second surface 12a of the substrate W (step ST2).

The graphene-containing film 14 is a carbon material film that mainly contains graphene configured as an aggregate of six-membered ring structures by covalent bonds (sp² bonds) of carbon atoms, and is formed as a film that inhibits (blocks) formation of a target film to be formed later.

The graphene-containing film 14 may be formed of graphene only, or may contain other carbon materials, such as graphite, diamond, charcoal, carbon nanotubes, or fullerenes, or amorphous components, in addition to graphene. The graphene-containing film 14 may be composed of graphene of at least 50% or more, and may be composed of graphene of 90% or more. In general, graphene can be more selectively attached to a metal than to an insulator. Therefore, when the second film 12 is the metal film, the graphene-containing film 14 is selectively formed on the second surface 12a of the second film 12.

The graphene-containing film 14 may be formed by a plasma chemical vapor deposition (CVD) method. The graphene-containing film 14 may also be formed by a plasma atomic layer deposition (ALD) method. A carbon-containing gas may be used as a raw material gas during film formation. In addition to the carbon-containing gas, H₂ gas or N₂ gas may be added. Further, a noble gas such as Ar, He, Ne, Kr, or Xe may be added as a plasma generation gas.

As the carbon-containing gas, for example, a hydrocarbon gas such as ethylene (C₂H₄), methane (CH₄), ethane (C₂H₆), propane (C₃H₈), propylene (C₃H₆), or acetylene (C₂H₂) may be used.

Plasma used to form the graphene-containing film 14 is not particularly limited, and various types of plasma such as capacitively coupled plasma, inductively coupled plasma, and microwave plasma may be used. Among the various types of plasma, the microwave plasma may be appropriately used. The microwave plasma is plasma with a high radical density and with a low electron temperature. Thus, the carbon-containing gas can be dissociated into a state appropriate for graphene growth at a relatively low temperature, and therefore, a high-quality film can be obtained. In addition, the graphene-containing film 14 can be formed on the second film 12 without damaging the second film 12, which is an underlying film, or a film, which is being formed.

A pressure when the graphene-containing film 14 is formed can be appropriately set according to plasma to be generated. A temperature when the graphene-containing film 14 is formed may be 250 to 450 degrees C., and may be 400 to 450 degrees C. In a case where the temperature is lower than 250 degrees C., an effect (blocking ability) of inhibiting formation of the target film even by next plasma processing tends to be low, and in a case where the temperature exceeds 450 degrees C., there is a concern that the second film 12 will be damaged when the second film 12 is the metal film.

A film thickness of the graphene-containing film 14 may be in a range of 0.5 to 10 nm, and may be in a range of 4 to 6 nm. When the film thickness is thinner than 0.5 nm, it is difficult to obtain the effect of inhibiting formation of the target film even by the next plasma processing, and there is a concern that the second film 12 will be damaged by the next plasma processing. On the other hand, when the film thickness exceeds 10 nm, carbon nanowires, carbon nanowalls, and the like are formed relatively in large quantities, and an unintended graphene-containing film may be formed. As a result, the effect of inhibiting film formation is likely to be lowered.

Subsequently, as illustrated in FIG. 2C, a process by hydrogen-containing plasma is performed on the substrate W after the graphene-containing film 14 is formed (step ST3).

The process by the hydrogen-containing plasma is a modification process of enhancing the effect of the graphene-containing film 14 that inhibits formation of the target film. Using graphene as a film formation inhibitor of the target film is disclosed in Patent Documents 3 and 4 described above. However, it has been found that a sufficient effect of inhibiting formation of the target film is not obtained only by simply forming the graphene. The reason is considered to be that only simply forming the graphene results in defects present on a surface of the graphene becoming a starting point for nucleation of the target film, and the formation of the target film progresses from the generated nuclei of the target film.

Therefore, after the graphene-containing film 14 is formed, the hydrogen-containing plasma processing is performed to repair (terminate) the defects present in the graphene of the graphene-containing film 14. Since hydrogen has a small atomic radius, hydrogen ions or radicals easily enter the film by generating plasma of the hydrogen-containing gas, and it is possible to repair the defects. That is, by the hydrogen-containing plasma processing, it is possible to modify the graphene-containing film 14 into a film having a high effect of inhibiting formation of the target film, and to form a modified graphene-containing film 14a.

The hydrogen-containing plasma can be formed by converting the hydrogen-containing gas into plasma. As the hydrogen-containing gas, hydrogen gas (H₂ gas) may be used. In addition to H₂ gas, NH₃ gas, H₂O gas, H₂O₂ gas, HF gas, and the like may be used. Further, hydrogen also includes deuterium, and the hydrogen-containing gas may be deuterium gas (D₂ gas) or heavy water (D₂O). Furthermore, in addition to the hydrogen-containing gases described above, an inert gas (e.g., a noble gas, such as Ar gas, or N₂ gas) may be used. As an example, H₂—Ar plasma by H₂ gas and Ar gas may be used.

The plasma used in the hydrogen-containing plasma processing is not particularly limited, and various types of plasma such as capacitively coupled plasma, inductively coupled plasma, and microwave plasma may be used. Since the microwave plasma has a high radical density and a low electron temperature, the microwave plasma processing can be performed efficiently with low damage.

The hydrogen-containing plasma processing in step ST3 may be performed in a processing container different from the film formation process of the graphene-containing film 14 in step ST2, or may be performed in the same processing container. When the same plasma source is used for both processes, the hydrogen-containing plasma processing in step ST3 and the film formation process of the graphene-containing film 14 in step ST2 may be performed in the same processing container.

The hydrogen-containing plasma processing in step ST3 may be performed under conditions of temperature: 100 to 400 degrees C., power: 50 to 3,000 W, and time: 1 to 60 seconds. A pressure during the hydrogen-containing plasma processing may be appropriately set according to the plasma to be generated.

Subsequently, as illustrated in FIG. 2D, a target film 15 is selectively formed on the first surface 11a of the substrate W (step ST4).

The target film 15 is not particularly limited but may be, for example, a SiO₂ film. The SiO₂ film can be appropriately formed by a process of coating the first surface 11a with a metal-containing catalyst layer and a process of exposing the substrate W after the coating to a processing gas including silanol gas, as disclosed in Patent Document 3.

The process of coating the first surface 11a of the first film 11 with the metal-containing catalyst layer can be performed by exposing the substrate W to a metal-containing gas. When the first film 11 is the insulating film and the second film 12 is the conductive film (metal film), the metal-containing gas can be selectively adsorbed to the first surface 11a, and the metal-containing catalyst layer can be selectively formed on the first surface 11a. The metal reacts to form a chemisorption layer with a thickness of less than a monolayer. Each gas pulse includes a purge or exhaust step to remove a residual gas from the processing container. Since the modified graphene-containing film has low reactivity, it is difficult for the metal-containing catalyst to be adsorbed to the modified graphene-containing film, and the metal-containing catalyst layer is selectively formed on the first surface 11a of the first film 11. As described below, the silanol gas selectively reacts with the metal-containing catalyst layer on the first surface 11a.

As a metal for forming the metal-containing catalyst layer, either one or both of Al and Ti can be used. Examples of the metal-containing catalyst layer include metallic Al, Al₂O₃, AlN, an Al alloy, an Al-containing precursor, metallic Ti, TiO₂, TiN, a Ti alloy, a Ti-containing precursor, TiAlN, TiAlC, and the like. As the Al-containing precursor, various materials including an organic Al compound such as AlMe₃ (TMA) can be used. Similarly, as the Ti-containing precursor, various materials including an organic Ti compound such as Ti(NEt₂)₄ (TDEAT) can be used.

As the silanol gas, for example, tris(tert-pentoxy)silanol (TPSOL), tris(tert-butoxy)silanol, or bis(tert-butoxy)(isopropoxy)silanol can be used. The processing gas may include an inert gas such as Ar gas in addition to the silanol gas.

At this time, a thickness of the SiO₂ film is controlled by self-limiting adsorption of the silanol gas onto the metal-containing catalyst layer. Catalytic action of the metal-containing catalyst layer continues until the film thickness reaches about 3 to 5 nm. The process of coating the metal-containing catalyst layer and the process of exposing the processing gas containing silanol are performed once or repeated multiple times to selectively form the SiO₂ film of a desired film thickness on the first surface 11a. The SiO₂ film can be formed without using plasma at a temperature of 150 degrees C. or less, specifically, 120 degrees C. or less, or more specifically, 100 degrees C.

The SiO₂ film may be formed by general CVD or ALD, as long as it is possible to form the SiO₂ film selectively.

The target film 15 may be, for example, an Al₂O₃ film, a SiN film, a ZrO₂ film, or a HfO₂ film, in addition to the SiO₂ film. These films can also be selectively formed on the first surface 11a of the first film 11 by CVD, ALD, or the like.

Subsequently, as illustrated in FIG. 2E, if necessary, an excess portion of the target film 15 is removed by etching (step ST5).

For example, when the barrier film 13 is provided as in this example, the target film 15 is also formed on the third surface 13a of the barrier film 13, and an end portion of the target film 15 may protrude from the first surface 11a. This protruding portion 15a becomes the excess portion. In addition, since the target film 15 is formed thicker than a desired thickness in a film thickness direction, the excess portion also exists in the thickness direction. In step ST5, the protruding portion 15a or the portion of the target film 15 that is thicker than the desired thickness is removed by etching as the excess portion.

The etching at this time is not particularly limited and can be performed by various methods. For example, when the target film 15 is the SiO₂ film, gas etching by HF gas and TMA gas or gas etching by HF gas and NH₃ gas can be performed without plasma. The gas etching by HF gas and TMA gas can be performed by atomic layer etching (ALE) that repeats a step of supplying HF gas to the surface of the SiO₂ film to fluorinate the surface and then a step of supplying TMA gas to remove fluoride by ligand exchange. Further, the gas etching by HF gas and NH₃ gas is known as chemical oxide removal (COR). Specifically, HF gas and NH₃ gas are adsorbed to the surface of the SiO₂ film and react with an oxide film to generate ammonium fluorosilicate (AFS), which is an ammonium fluoride-based compound, and the AFS is removed by heating.

In addition, regardless of the material of the target film 15, H₂ plasma processing or plasma etching using a CF-based gas, which has been conventionally and generally performed, may be used.

In addition, the etching in step ST5 is not essential. The etching in step ST5 may not be performed in a case where the target film 15 is not likely to protrude from the first surface 11a and the thickness of the target film 15 is a desired thickness, for example, when the second film 12 is formed without using a barrier film or when the graphene-containing film 14 is also formed on the barrier film 13.

By steps ST1 to ST5 described above, the target film 15 can be selectively formed only on the first surface 11a of the first film 11.

Although the case in which steps ST1 to ST5 are performed sequentially has been described, steps ST3 and ST4 may be performed repeatedly. This is effective in a case in which the effect of inhibiting formation of the graphene-containing film 14 weakens while the target film 15 is being formed in step ST4. In that case, the hydrogen-containing plasma processing of step ST3 may be performed under different conditions between the first execution and the second or later execution, or under the same conditions.

As disclosed in Patent Documents 1 and 2 and Non-Patent Document 1, when the SAM is used as the film formation inhibitor that inhibits formation of the target film, multiple steps such as an oxidation process and a plasma process are performed. Thus, multiple processes including heating are performed on the metal surface of the second film. Since the SAM itself is a molecular adsorption layer and has a film thickness of only about 1 nm at most, the metal film is easily damaged by the multiple processes performed on the metal surface of the second film. Further, since the SAM has a thickness of about 1 nm, even when selective film formation is performed, there are cases in which lateral growth of the target film is not suppressed. Furthermore, when the second film is a Ru film, it is difficult to inhibit film formation by the SAM.

In contrast, as disclosed in Patent Documents 3 and 4, when graphene is used as the film formation inhibitor for the target film, the film thickness can be increased to a certain extent. Thus, even when the second film as a base is the metal layer, it is considered that damage can be reduced and lateral growth of the target film can be suppressed. However, as described above, it has been found that it is difficult to secure desired selectivity by simply forming the graphene, because surface defects of the graphene serve as starting points of nucleation of the target film and the effect of inhibiting formation of the target film is not obtained sufficiently.

For the reasons described above, in the present embodiment, after forming the graphene-containing film 14 on the second surface 12a of the second film 12, the process by the hydrogen-containing plasma is performed. Thus, it is possible to repair (terminate) and modify defects present in the graphene of the graphene-containing film 14, and to sufficiently secure the effect of inhibiting formation of the target film with respect to the second film 12. Therefore, the target film 15 can be selectively formed on the first surface 11a of the first film 11 with higher precision while suppressing damage.

In addition, a higher effect can be obtained by adjusting a film thickness or a temperature when forming the graphene-containing film 14. In addition, by using the graphene-containing film 14 as the film formation inhibitor, it is possible to form the target film selectively even when, for example, the SiO₂ film is used as the first film 11 and the Ru film is used as the second film 12.

### Second Embodiment

Next, a second embodiment will be described.

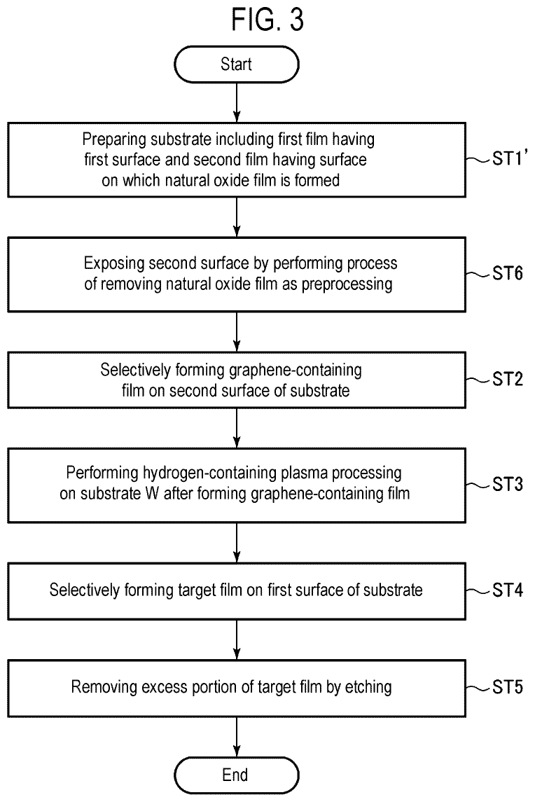

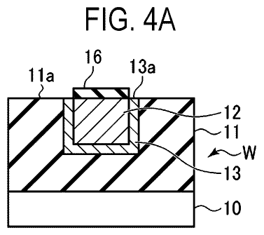

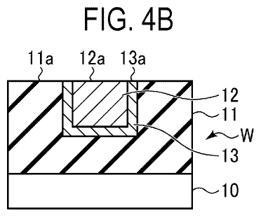

FIG. 3 is a flowchart illustrating a film forming method according to the second embodiment, and FIGS. 4A and 4B are cross-sectional views illustrating a part of processes of the film forming method according to the second embodiment.

In the present embodiment, a preprocessing process is added to the film forming method described in the first embodiment.

In the substrate W having the structure of FIG. 2A, when the second film 12 is made of a metal, as the substrate W is maintained in the air, a native oxide film 16 may be formed on the surface of the second film 12 as illustrated in FIG. 4A. In such a case, since the second surface 12a for forming the graphene-containing film 14 is not exposed, it is necessary to remove the native oxide film 16 prior to the formation of the graphene-containing film 14 in step ST2.

That is, in the present embodiment, first, as illustrated in FIG. 4A, the substrate W including the first film 11 having the first surface 11a and the second film 12 having a surface on which the native oxide film 16 is formed is prepared (step ST1′).

Subsequently, as illustrated in FIG. 4B, the second surface 12a of the second film 12 is exposed by performing, as preprocessing, a process of reducing and removing the native oxide film 16 (step ST6).

Step ST6 can be performed by, for example, hydrogen annealing or hydrogen plasma processing. In this case, a temperature may be set to be 500 degrees C. or less. The hydrogen plasma processing can be performed at a temperature lower than that of the hydrogen annealing. The hydrogen annealing is performed by introducing hydrogen gas (H₂ gas) into the processing container while heating the substrate W in the processing container. The hydrogen plasma processing is performed by applying hydrogen plasma to the substrate W in the processing container. Both the hydrogen annealing and the hydrogen plasma processing may be performed using H₂ gas alone, or may be performed by adding an inert gas such as Ar gas to H₂ gas.

Thereafter, as in the first embodiment, the process of selectively forming the graphene-containing film 14 in step ST2, the process of performing the hydrogen-containing plasma processing in step ST3, and the process of selectively forming the target film in step ST4 are performed, and as necessary, the process of etching in step ST5 is performed.

### Third Embodiment

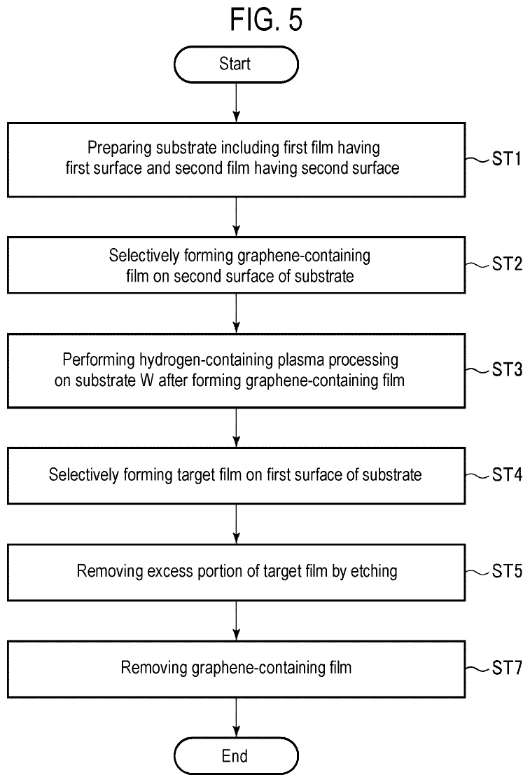

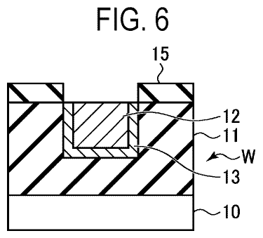

FIG. 5 is a flowchart illustrating a film forming method according to a third embodiment, and FIG. 6 is a cross-sectional view illustrating a part of processes in FIG. 5.

In the third embodiment, after steps ST1 to ST5 are performed as in the first embodiment, the graphene-containing film 14a is removed as illustrated in FIG. 6 (step ST7). Step ST7 is a process performed when necessary according to the circumstances of a device. Step ST7 may be performed after steps ST1′ to ST5 are performed as in the second embodiment.

Step ST7 can be performed by, for example, hydrogen plasma processing. In this case, a temperature may be set to be 500 degrees C. or less. The hydrogen plasma processing is performed by applying hydrogen plasma to the substrate W placed in the processing chamber. The hydrogen plasma processing may be performed using H₂ gas alone, or may be performed by adding an inert gas such as Ar gas to H₂ gas.

### Film Forming Apparatus

Next, a film forming apparatus for implementing the film forming method described above will be described.

### Overall Configuration

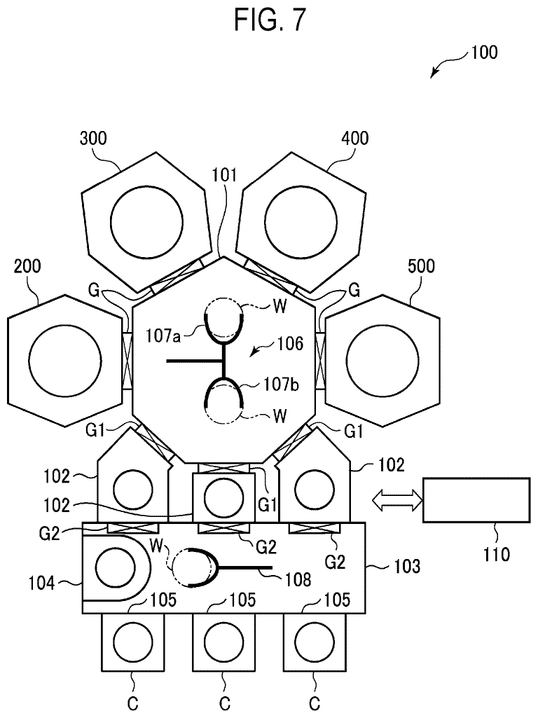

FIG. 7 is a schematic diagram illustrating an overall configuration of an example of a film forming apparatus capable of implementing a film forming method according to an embodiment. A film forming apparatus 100 of FIG. 7 is a multi-chamber type apparatus capable of implementing the film forming method according to the first embodiment, and is configured as an apparatus capable of implementing steps ST2 to ST5 described above in-situ.

As illustrated in FIG. 7, the film forming apparatus 100 has a graphene-containing film formation module 200, a hydrogen-containing plasma processing module 300, a target film formation module 400, and an etching module 500. These modules are connected to a vacuum transfer chamber 101 via gate valves G, respectively. An interior of the vacuum transfer chamber 101 is exhausted by a vacuum pump and maintained at a predetermined vacuum level.

The graphene-containing film formation module 200 selectively forms the graphene-containing film on a second surface of the substrate W by plasma CVD or plasma ALD.

The hydrogen-containing plasma processing module 300 processes the substrate W after the graphene-containing film is formed by hydrogen-containing plasma to modify the graphene-containing film.

The target film formation module 400 selectively forms a target film, for example, a SiO₂ film, on a first surface of the substrate W.

The etching module 500 removes an excess portion of the target film by etching.

Three load lock chambers 102 are connected to three different walls of the vacuum transfer chamber 101 via gate valves G1. An atmospheric transfer chamber 103 is provided on an opposite side of the vacuum transfer chamber 101 with the load lock chambers 102 interposed therebetween. The three load lock chambers 102 are connected to the atmospheric transfer chamber 103 via gate valves G2. The load lock chambers 102 serve to perform pressure control between atmospheric pressure and vacuum when transferring the substrate W between the atmospheric transfer chamber 103 and the vacuum transfer chamber 101.

A wall of the atmospheric transfer chamber 103 opposite to a wall to which the load lock chambers 102 are installed has three carrier installation ports 105 for installing carriers (FOUPs, and the like) C each accommodating the substrate W. In addition, an alignment chamber 104 for aligning the substrate W is provided on a side wall of the atmospheric transfer chamber 103. Downflow of clean air is formed inside the atmospheric transfer chamber 103.

A first transfer mechanism 106 is provided in the vacuum transfer chamber 101. The first transfer mechanism 106 transfers the substrate W with respect to the graphene-containing film formation module 200, the hydrogen-containing plasma processing module 300, the target film formation module 400, the etching module 500, and the load lock chambers 102. The first transfer mechanism 106 has two transfer arms 107a and 107b capable of moving independently.

A second transfer mechanism 108 is provided in the atmospheric transfer chamber 103. The second transfer mechanism 108 is configured to transfer the substrate W with respect to the carriers C, the load lock chambers 102, and the alignment chamber 104.

The film forming apparatus 100 has an overall controller 110. The overall controller 110 has a main controller having a CPU (computer), an input device, an output device, a display device, and a memory device. The main controller controls individual components of the graphene-containing film formation module 200, the hydrogen-containing plasma processing module 300, the target film formation module 400, the etching module 500, the vacuum transfer chamber 101, and the load lock chambers 102. The main controller of the overall controller 110 executes an operation for performing film formation in the film forming apparatus 100 based on a processing recipe stored in, for example, a storage medium mounted in the memory device or a storage medium set in the memory device. In addition, the overall controller 110 may be configured as a high-level controller by providing a low-level controller in each module.

In the film forming apparatus 100 configured as described above, the second transfer mechanism 108 takes the substrate W out of the carrier C connected to the atmospheric transfer chamber 103, and loads the substrate W into one of the load lock chambers 102 via the alignment chamber 104. Then, after vacuum-exhausting an interior of the load lock chamber 102, the first transfer mechanism 106 transfers the substrate W to the graphene-containing film formation module 200, the hydrogen-containing plasma processing module 300, the target film formation module 400, and the etching module 500 to perform the processes of steps ST2 to ST5 described above.

After the above processes are completed, the first transfer mechanism 106 transfers the substrate W to one of the load lock chambers 102, and the second transfer mechanism 108 returns the substrate W in the load lock chamber 102 to the carrier C.

The processes described above are performed continuously and simultaneously in parallel for a plurality of substrates W, thereby completing film formation for a predetermined sheets of substrates W.

In the film forming apparatus 100, the processes of steps ST2 to ST5 are performed in separate single-wafer type modules. Thus, since it is easy to set an optimum temperature for each process, and the series of processes can be performed without breaking vacuum, it is possible to suppress oxidation during the processes.

Although a case in which steps ST2 to ST5 are performed in separate modules in the film forming apparatus 100 has been described, two or more steps may be performed in the same module. In addition, when performing the preprocessing process of step ST6 and the graphene-containing film removal process of step ST7, a size of the vacuum transfer chamber 101 may be changed to connect a preprocessing module and a graphene-containing film removal module to the vacuum transfer chamber 101, or these processes may be performed in other modules. In addition, the film forming apparatus is not limited to that illustrated in FIG. 7, and a connection type of each module to the vacuum transfer chamber may be arbitrary. In addition, without connecting each module to the vacuum transfer chamber, the substrate may be serially transferred to each module.

### Example of Graphene-Containing Film Formation Module

Next, an example of a graphene-containing film formation module will be described.

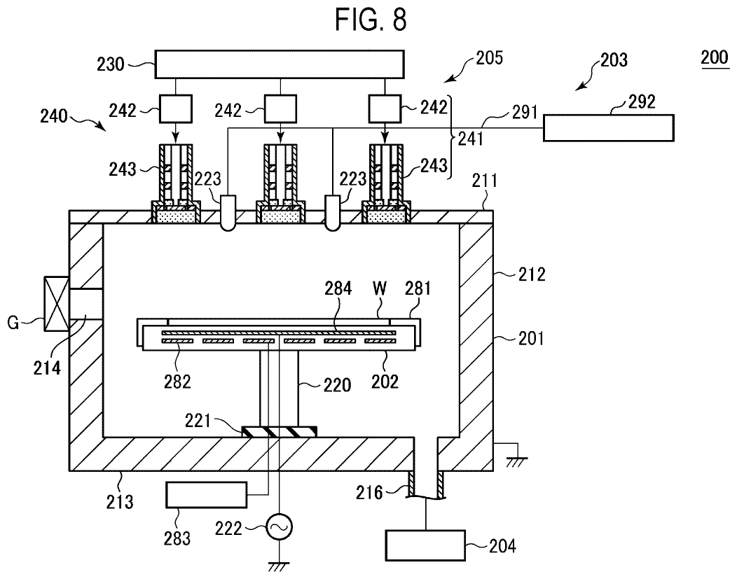

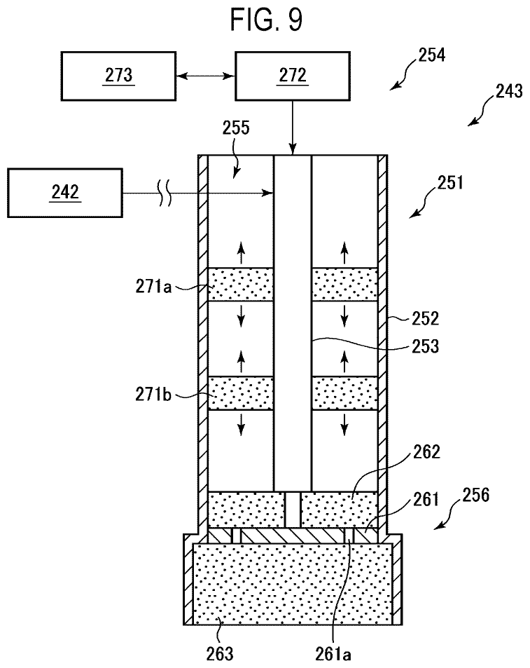

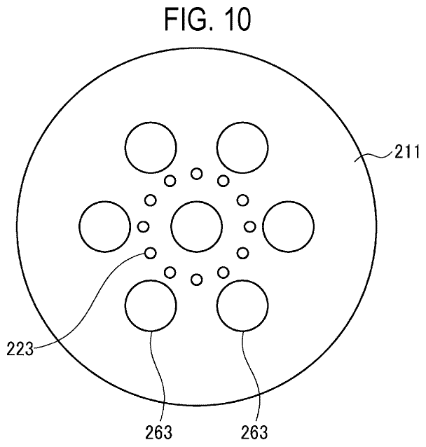

FIG. 8 is a cross-sectional view schematically illustrating an example of a graphene-containing film formation module, FIG. 9 is a cross-sectional view schematically illustrating a microwave radiation mechanism in the graphene-containing film formation module of FIG. 8, and FIG. 10 is a bottom view schematically illustrating a ceiling wall of a processing container in the graphene-containing film formation module of FIG. 8.

The graphene-containing film formation module 200 is configured as a microwave plasma processing apparatus and includes a processing container 201, a stage 202, a gas supply 203, an exhaust device 204, and a microwave introduction device 205.

The processing container 201 accommodates a substrate W and is formed of a metallic material such as aluminum (Al) or an alloy thereof. The processing container 201 has a substantially cylindrical shape, and includes a ceiling wall 211 and a bottom wall 213, which are plate-shaped, and a side wall 212 connecting the ceiling wall 211 and the bottom wall 213. Inner surfaces of the ceiling wall 211 and the side wall 212 constitute an inner wall of the processing container 201. A surface of the inner wall of the processing container 201 may be coated with Al₂O₃ or Y₂O₃.

The microwave introduction device 205 is provided above the processing container 201 and functions as a plasma generating means for generating plasma by introducing electromagnetic waves (microwaves) into the processing container 201. The microwave introduction device 205 will be described in detail later.

The ceiling wall 211 has a plurality of openings into which microwave radiation mechanisms and gas introduction nozzles of the microwave introduction device 205, which will be described later, are inserted. The side wall 212 has a loading/unloading port 214 for loading and unloading the substrate W into and from the vacuum transfer chamber 101 adjacent to the processing container 201. The loading/unloading port 214 is opened and closed by a gate valve G. The bottom wall 213 is provided with the exhaust device 204. The exhaust device 204 is provided in an exhaust pipe 216 connected to the bottom wall 213 and includes a vacuum pump and a pressure control valve. An interior of the processing container 201 is exhausted via the exhaust pipe 216 by the vacuum pump of the exhaust device 204. A pressure inside the processing container 201 is controlled by the pressure control valve.

The stage 202 is disposed inside the processing container 201 and places the substrate W thereon. The stage 202 has a disk shape and is made of, for example, a ceramic material such as AIN. The stage 202 is supported by a cylindrical support 220 extending upward from a center of a bottom of the processing container 201. A support plate 221 is provided between the bottom wall 213 of the processing container 201 and the support 220. The support 220 and the support plate 221 are made of, for example, a ceramic material such as AlN. A guide ring 281 for guiding the substrate W is provided on an outer peripheral portion of the stage 202. In addition, lift pins (not illustrated) for raising and lowering the substrate W are provided inside the stage 202 so as to protrude and retract with respect to an upper surface of the stage 202. In addition, a heater 282 of a resistance heating type is embedded inside the stage 202, and the heater 282 heats the substrate W placed on the stage 202 via the stage 202 by being fed with power from a heater power supply 283. Further, a thermocouple (not illustrated) is inserted into the stage 202, and a heating temperature of the substrate W can be controlled based on a signal from the thermocouple. In addition, an electrode 284 having the same size as the substrate W is embedded in the stage 202 at a location above the heater 282, and a radio-frequency bias power supply 222 is electrically connected to the electrode 284. Radio-frequency bias for attracting ions is applied from the radio-frequency bias power supply 222 to the stage 202. The radio-frequency bias power supply 222 may not be provided according to characteristics of plasma processing.

The gas supply 203 serves to supply a plasma generation gas (a noble gas such as Ar gas), a carbon-containing gas for forming a graphene film (e.g., a hydrocarbon gas such as ethylene (C₂H₄), methane (CH₄), ethane (C₂H₆), propane (C₃H₈), propylene (C₃H₆), acetylene (C₂H₂), and the like), and the like into the processing container 201. In addition, the gas supply 203 may supply H₂ gas or N₂ gas. The gas supply 203 has a gas supply mechanism 292, which includes a plurality of gas sources for supplying the gases described above, pipes respectively connected to the gas sources, valves or flow rate controllers provided on the pipes, and the like. In addition, the gas supply 203 further has a common pipe 291 for guiding the gases from the gas supply mechanism 292, and a plurality of gas introduction nozzles 223 connected to the pipe 291. The gas introduction nozzles 223 are inserted into the openings formed in the ceiling wall 211 of the processing container 201, and the gases from the gas supply mechanism 292 are introduced into the processing container 201 via the pipe 291 and the gas introduction nozzles 223. In addition, dissociation of the gases may be adjusted by adjusting a distance of a position where the gases are introduced from the substrate W by an appropriate means.

As described above, the microwave introduction device 205 is provided above the processing container 201, and functions as a plasma generating means that introduces electromagnetic waves (microwaves) into the processing container 201 to generate plasma. As illustrated in FIG. 8, the microwave introduction device 205 includes the ceiling wall 211 that functions as a ceiling plate, a microwave output 230, and an antenna unit 240.

The microwave output 230 generates microwaves, and distributes and outputs the microwaves to a plurality of paths. The microwave output 230 includes a microwave power source, a microwave oscillator, an amplifier, and a distributor. The microwave oscillator is a solid state oscillator and oscillates (e.g., PLL oscillation) the microwaves at, for example, 860 MHz. A frequency of the microwaves is not limited to 860 MHz, and may be in a range of 700 MHz to 10 GHz, such as 2.45 GHz, 8.35 GHz, 5.8 GHz, 1.98 GHz, and the like. The microwaves oscillated by the microwave oscillator are amplified by the amplifier and distributed to the plurality of paths by the distributor. The distributor distributes the microwaves while matching impedances of an input side and an output side.

The antenna unit 240 introduces the microwaves output from the microwave output 230 into the processing container 201. The antenna unit 240 includes a plurality of antenna modules 241. Each of the antenna modules 241 introduces the microwaves distributed by the distributor into the processing container 201. Each of the antenna modules 241 includes an amplifier 242 that mainly amplifies and outputs the distributed microwaves, and a microwave radiation mechanism 243 that radiates the microwaves output from the amplifier 242 into the processing container 201.

The amplifier 242 includes a phase shifter, a variable gain amplifier, a main amplifier, and an isolator, which are disposed in this order from an upstream side. The phase shifter adjusts a phase of the microwaves, and the variable gain amplifier adjusts a power level of the microwaves. Thereafter, the main amplifier amplifies the microwaves. The main amplifier is configured as a solid-state amplifier. The isolator isolates reflected microwaves that are reflected by an antenna of the microwave radiation mechanism 243, which will be described later, and then travel toward the main amplifier.

As illustrated in FIG. 8, the microwave radiation mechanisms 243 are provided on the ceiling wall 211. In addition, as illustrated in FIG. 9, the microwave radiation mechanism 243 has a coaxial tube 251, a power feeder 255, a tuner 254, and an antenna 256. The coaxial tube 251 has a cylindrical outer conductor 252 and an inner conductor 253, which is disposed in the outer conductor 252 and provided coaxially with the outer conductor 252, and a microwave transmission path is provided between the outer conductor 252 and the inner conductor 253.

The power feeder 255 feeds the microwaves amplified by the amplifier 242 to the microwave transmission path. The microwaves amplified by the amplifier 242 are introduced into the power feeder 255 from a lateral side of an upper end portion of the outer conductor 252 by a coaxial cable. The microwave power is fed to the microwave transmission path provided between the outer conductor 252 and the inner conductor 253, and propagates toward the antenna 256.

The antenna 256 radiates the microwaves from the coaxial tube 251 into the processing container 201, and is provided at a lower end portion of the coaxial tube 251. The antenna 256 has a disk-shaped planar antenna 261 connected to a lower end of the inner conductor 253, a wave retarder 262 disposed on an upper surface of the planar antenna 261, and a microwave transmission plate 263 disposed on a lower surface of the planar antenna 261. The microwave transmission plate 263 is inserted into the ceiling wall 211, and a lower surface thereof is exposed to an internal space of the processing container 201. The planar antenna 261 has a slot 261a formed to penetrate the planar antenna 261. A shape of the slot 261a is appropriately set so that the microwaves are efficiently radiated. A dielectric may be inserted into the slot 261a. The wave retarder 262 is formed of a material having a dielectric constant greater than that of vacuum, and the phase of the microwaves can be adjusted by a thickness of the wave retarder 262, so that radiation energy of the microwaves can be maximized. The microwave transmission plate 263 is also made of a dielectric material and has a shape capable of radiating the microwaves in TE mode efficiently. The microwaves transmitted through the microwave transmission plate 263 generate plasma in an internal space of the processing container 201. As the materials constituting the wave retarder 262 and the microwave transmission plate 263, for example, quartz or ceramic, a fluorine-based resin such as a polytetrafluoroethylene resin, and a polyimide resin can be used.

The tuner 254 serves to match an impedance of a load to a characteristic impedance of a microwave power source in the microwave output 230. The tuner 254 constitutes a slug tuner. For example, as illustrated in FIG. 9, the tuner 254 has two slugs 271a and 271b, an actuator 272 that drives the two slugs 271a and 271b individually, and a tuner controller 273 that controls the actuator 272. The slugs 271a and 271b are disposed closer to a base end (upper end) of the coaxial tube 251 than the antenna 256.

The slugs 271a and 271b have a plate and annular shape and are made of a dielectric material such as a ceramic material. The slugs 271a and 271b are disposed between the outer conductor 252 and the inner conductor 253 of the coaxial tube 251. In addition, the actuator 272 may have two screws, which are provided, for example, inside the inner conductor 253 and to which the slugs 271a and 271b are respectively screw-coupled, and a motor for rotating the screws. For example, the slugs 271a and 271b are driven individually by rotating the screws using the motor. The actuator 272 moves the slugs 271a and 271b in a vertical direction based on a command from the tuner controller 273 to adjust positions of the slugs 271a and 271b so that an impedance of a terminal portion becomes 50 ohms.

The main amplifier of the amplifier 242, the tuner 254, and the planar antenna 261 are disposed in close proximity to one another. The tuner 254 and the planar antenna 261 form a lumped constant circuit and function as a resonator. Although there is an impedance mismatch at an installation portion of the planar antenna 261, the tuner 254 directly tunes a plasma load. Thus, tuning a load impedance including plasma can be performed with high precision. Therefore, it is possible to eliminate an effect of reflection at the planar antenna 261.

As illustrated in FIG. 10, in this example, seven microwave radiation mechanisms 243 are provided, and the corresponding microwave transmission plates 263 are evenly disposed in a hexagonal close-packed arrangement. That is, one of the seven microwave transmission plates 263 is disposed in a center of the ceiling wall 211, and the other six microwave transmission plates 263 are disposed therearound. These seven microwave transmission plates 263 are disposed so that adjacent microwave transmission plates are equi-spaced. In addition, the nozzles 223 of the gas supply 203 are disposed to surround a periphery of the center-positioned microwave transmission plate. In addition, the number of the microwave radiation mechanisms 243 is not limited to seven.

When forming the graphene-containing film by the graphene-containing film formation module 200 configured as described above, first, the substrate W is loaded into the processing container 201 and placed on the stage 202.

Subsequently, after stabilizing a temperature of the substrate W, an internal pressure of the processing container 201 is controlled, and a graphene-containing film is formed by, for example, microwave plasma CVD.

Specifically, Ar gas, which is a plasma generation gas, is supplied from the gas introduction nozzle 223 to directly below the ceiling wall 211 of the processing container 201. In addition, microwaves that are distributed into multiple paths and output from the microwave output 230 of the microwave introduction device 205 are radiated into the processing container 201 via the antenna modules 241 of the antenna unit 240 to ignite plasma.

In each antenna module 241, the microwaves are individually amplified by the main amplifier of the amplifier 242 and are fed to each microwave radiation mechanism 243. The microwave power fed to the microwave radiation mechanism 243 is transmitted to the coaxial tube 251 and reaches the antenna 256. At this time, an impedance of the microwaves is automatically matched by the slugs 271a and 271b of the tuner 254, and in a state without having power reflection substantially, the microwaves from the tuner 254 are radiated from the slot 261a of the planar antenna 261 via the wave retarder 262 of the antenna 256. Then, the microwaves pass through the microwave transmission plate 263, and are transmitted to a surface (lower surface) of the microwave transmission plate 263 in contact with plasma to form surface waves. Thus, surface wave plasma by Ar gas is generated in a region directly below the ceiling wall 211.

At a timing when the plasma is ignited, a carbon-containing gas, for example, C₂H₄ gas, as a raw material gas for film formation, is supplied from the gas introduction nozzle 223. In this case, N₂ gas or H₂ gas may be supplied as necessary.

The gases described above are excited and dissociated by the plasma and supplied to the substrate W placed on the stage 202. Since the substrate W is disposed in a region spaced apart from a plasma generation region and the plasma diffused from the plasma generation region is supplied to the substrate W, the plasma on the substrate W has a low electron temperature and low damage, and is high-density plasma constituted mainly by radicals. Therefore, nucleation and lateral growth proceed well, and graphene crystals with few defects grow. As a result, the graphene-containing film of good quality, which can be a film inhibiting formation of the target film, is formed.

From the viewpoint of using the graphene-containing film as a film that inhibits formation of the target film, a substrate temperature when forming the graphene-containing film may be 250 to 450 degrees C., and a film thickness may be 0.5 to 10 nm.

In addition, although C₂H₄ gas as a carbon-containing gas is supplied to the plasma generation region and dissociated in this example, dissociation may be suppressed by dissociating the carbon-containing gas with plasma diffused from the plasma generating region by an appropriate means. Alternatively, the carbon-containing gas such as C₂H₄ gas may be supplied to the plasma generation region and ignite plasma directly without using Ar gas as a plasma generation gas.

In the graphene-containing film formation module 200 of this example, the microwaves distributed into multiple paths are amplified individually by the amplifiers 242 and radiated individually from the microwave radiation mechanisms 243 to generate microwave plasma. Thus, a large-sized isolator or synthesizer is not necessary, and the graphene-containing film formation module 200 can be made compact. Further, at the installation portion of the planar slot antenna where an impedance mismatch exists, the tuner 254 can tune the load impedance including the plasma with high precision. Thus, it is possible to eliminate the influence of reflection reliably and control the plasma with high precision. Furthermore, by providing the plurality of microwave transmission plates 263 as described above, it is possible to reduce a total area of a microwave transmission region, compared with a microwave plasma source having a single microwave transmission path and a single microwave transmission plate. Thus, it is possible to reduce microwave power required to stably ignite and discharge plasma.

In addition, without being limited to the microwave plasma processing apparatus as in this example, the graphene-containing film formation module may use other types of plasma, such as a capacitively coupled plasma processing apparatus or an inductively coupled plasma processing apparatus.

### Example of Hydrogen-Containing Plasma Processing Module

Next, an example of a hydrogen-containing plasma processing module will be described.

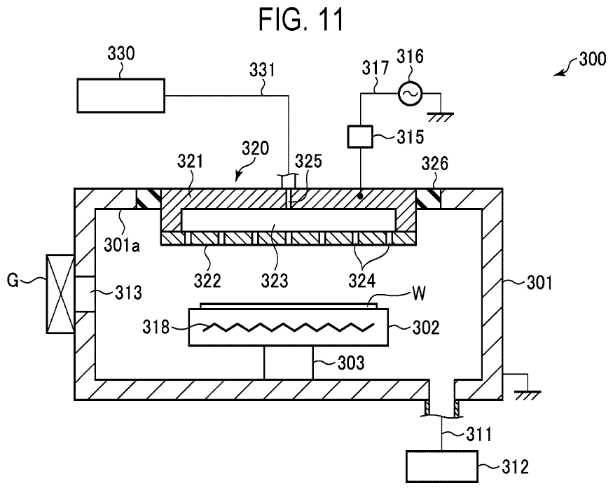

FIG. 11 is a cross-sectional view schematically illustrating an example of a hydrogen-containing plasma processing module. The hydrogen-containing plasma processing module 300 has a metallic processing container 301 having a substantially cylindrical shape. An exhaust pipe 311 is connected to a bottom surface of the processing container 301, and an exhaust mechanism 312, which has an automatic pressure control valve for controlling an internal pressure of the processing container 301 and a vacuum pump for exhausting an interior of the processing container 301, is provided in the exhaust pipe 311. By the exhaust mechanism 312, it is possible to vacuum-exhaust the interior of the processing container 301 and control the internal pressure to a desired level.

In a side wall of the processing container 301, a loading/unloading port 313 for loading and unloading the substrate W between the processing container 301 and the vacuum transfer chamber 101 adjacent thereto and a gate valve G for opening and closing the loading/unloading port 313 are provided.

A stage 302 for supporting the substrate W horizontally is provided inside the processing container 301. The stage 302 is supported at a center of a bottom wall of the processing container 301 via a support 303.

The stage 302 is grounded via the processing container 301 and functions as a lower electrode. The stage 302 may be made of a metal or ceramic material, and when the stage 302 is made of a ceramic material, an electrode plate is provided therein. A heater 318 for heating the substrate W is provided inside the stage 302. In the stage 302, a plurality of lifting pins (not illustrated) for supporting and raising/lowering the substrate W is provided to protrude and retract with respect to a surface of the stage 302.

A circular hole is formed in a ceiling wall 301a of the processing container 301, and a disk-shaped shower head 320 functioning as an upper electrode is inserted into the hole via an insulator 326. The shower head 320 has a base 321 and a shower plate 322. A gas diffusion space 323 is formed between the base 321 and the shower plate 322. A plurality of gas discharge holes 324, which penetrates from the gas diffusion space 323 into the processing container 301, is formed in the shower plate 322. A gas introduction hole 325 is formed in a center of the base 321 to penetrate into the gas diffusion space 323. A pipe 331 extending from a gas supply 330 is connected to the gas introduction hole 325, and a gas from the gas supply 330 is discharged into the processing container 301 via the shower head 320.

The gas supply 330 supplies a hydrogen-containing gas such as H₂ gas. In addition to the hydrogen-containing gas, a noble gas such as Ar gas or an inert gas such as N₂ gas may be supplied. In addition to H₂ gas, NH₃ gas, H₂O gas, H₂O₂ gas, HF gas, or the like may be used as the hydrogen-containing gas.

A radio-frequency power supply 316 is connected to the shower head 320, which functions as an upper electrode, via a power feeding line 317. A matcher 315 is connected to a middle of the power feeding line 317. A radio-frequency electric field is formed between the shower head 320 and the stage 302 by applying radio-frequency power from the radio-frequency power supply 316 to the shower head 320. Then, the hydrogen-containing gas supplied from the gas supply 330 is excited by the radio-frequency electric field to generate hydrogen-containing plasma.

In the hydrogen-containing plasma processing module configured as described above, first, the substrate W after the graphene-containing film is formed is loaded into the processing container 301 and placed on the stage 302.

Subsequently, after the temperature of the substrate W is stabilized, the internal pressure of the processing container 301 is controlled, and the hydrogen-containing gas such as H₂ gas and, when necessary, the inert gas are supplied from the gas supply 330 into the processing container 301 via the shower head 320. Then, in a state in which the gases are supplied, the radio-frequency power is applied from the radio-frequency power supply 316 to the shower head 320, thereby generating the hydrogen-containing plasma between the shower head 320 and the stage 302. As a result, hydrogen-containing plasma processing is performed on the substrate W.

By the hydrogen-containing plasma processing, the graphene-containing film formed on the substrate W can be modified into a film having a high effect of inhibiting formation of the target film.

In this example, a case in which capacitively coupled plasma is generated as the hydrogen-containing plasma has been described, but other types of plasma such as inductively coupled plasma and microwave plasma may be used. Since the microwave plasma has a high radical density and a low electron temperature, processing can be performed efficiently with little damage. In the case of the microwave plasma, a module having the same configuration as the graphene-containing film formation module 200 described above can be used. In addition, when the microwave plasma is used, the graphene-containing film formation module 200 may have the function of the hydrogen-containing plasma processing module 300, and after forming the graphene-containing film, the hydrogen-containing plasma processing may be performed continuously in the same processing container.

### Example of Target Film Formation Module

Next, an example of a target film formation module will be described.

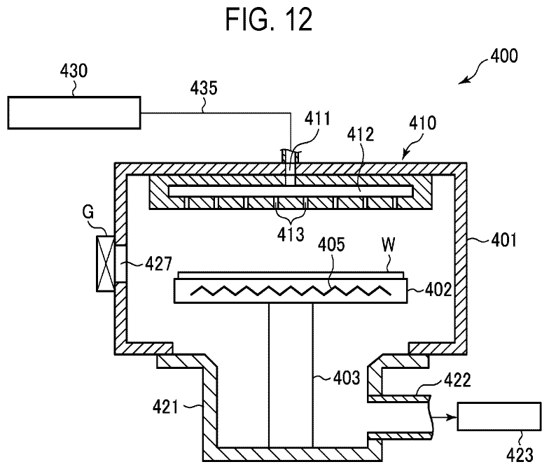

FIG. 12 is a cross-sectional view schematically illustrating an example of a target film formation module. The target film formation module 400 has a hermetic and substantially cylindrical processing container 401. In the processing container 401, a stage 402 for placing the substrate W horizontally is disposed and supported by a cylindrical support 403 provided at a center of a bottom wall of the processing container 401. The stage 402 is provided with a heater 405 for heating the substrate W. In the stage 402, a plurality of lifting pins (not illustrated) for supporting and raising/lowering the substrate W is provided to protrude and retract with respect to a surface of the stage 402.

A shower head 410 for introducing a processing gas for forming the target film into the processing container 401 in a shower form is provided on a ceiling wall of the processing container 401 to face the stage 402. The shower head 410 serves to discharge a gas supplied from a gas supply 430 to be described later into the processing container 401, and a gas introduction port 411 for introducing the gas is formed at an upper portion of the shower head 410. In addition, a gas diffusion space 412 is formed inside the shower head 410, and a plurality of gas discharge holes 413 in communication with the gas diffusion space 412 is formed at a bottom surface of the shower head 410.

An exhaust chamber 421 protruding downward is provided at the bottom wall of the processing container 401. An exhaust pipe 422 is connected to a side surface of the exhaust chamber 421, and an exhaust device 423 having a vacuum pump or a pressure control valve is connected to the exhaust pipe 422. By operating the exhaust device 423, it is possible to maintain a predetermined depressurized (vacuum) state inside the processing container 401.

A loading/unloading port 427 for loading and unloading the substrate W between the processing container 401 and the vacuum transfer chamber 101 is provided in a side wall of the processing container 401, and the loading/unloading port 427 is opened and closed by a gate valve G.

The gas supply 430 supplies gases necessary for forming the target film. When the target film is a SiO₂ film, the gas supply 430 supplies, for example, a metal-containing gas for forming a metal-containing catalyst layer and a silanol-containing processing gas. In addition to silanol, an inert gas such as Ar gas may be supplied as the processing gas. As a metal for forming the metal-containing catalyst layer, either one or both of Al and Ti can be used. As the metal-containing gas, an organic Al compound such as AlMe₃ (TMA) can be used as an Al precursor. A pipe 435 extends from the gas supply 430 and is connected to the gas introduction port 411.

In the target film formation module 400 configured as described above, the gate valve G is opened, and the substrate W is loaded into the processing container 401 via the loading/unloading port 427 and placed on the stage 402. The stage 402 is heated to a predetermined temperature by the heater 405, and the substrate W placed on the stage 402 is heated to that temperature. Further, the interior of the processing container 401 is exhausted by the vacuum pump of the exhaust device 423, and the internal pressure of the processing container 401 is adjusted to a predetermined pressure.

Subsequently, TMA gas, for example, is supplied from the gas supply 430 as the metal-containing gas, and the metal-containing catalyst layer is selectively formed on the first surface of the substrate W. Then, the silanol-containing processing gas is supplied to the metal-containing catalyst layer. A process of coating the metal-containing catalyst layer and a process of supplying the silanol-containing processing gas are performed once or repeated multiple times, and a SiO₂ film of a desired thickness is selectively formed on the first surface of the substrate W. The SiO₂ film can be formed without using plasma at a temperature of 150 degrees C. or less, specifically, 120 degrees C. or less, or more specifically, 100 degrees C.

The target film may be formed by CVD or ALD, and even in this case, a module having the same configuration as the target film formation module 400 can be used.

### Example of Etching Module

As described above, the etching module 500 serves to remove an excess portion of the target film formed on the first surface of the substrate W, and when the target film 15 is a SiO₂ film, etching can be performed without plasma by gas etching using HF gas and TMA gas or gas etching using HF gas and NH₃ gas. In this case, a module having the same configuration as the target film formation module 400 described above can be used.

In addition, the etching can be performed by H₂ plasma processing or plasma etching using a CF-based gas, which has been conventionally and generally performed. In this case, a module, which is capable of generating plasma and has the same configuration as the hydrogen-containing plasma processing module 300 described above, can be used. In this case, radio-frequency power may be applied to the stage.

In addition, as described above, step ST5 may not be performed, and when step ST5 is not performed, the etching module 500 is not necessary.

The film forming apparatus 100 described above can perform the film forming method of the first embodiment. When performing the second embodiment or the third embodiment, a film forming apparatus, which further includes at least one of a module for performing the preprocessing of step ST6 or a module for performing the graphene-containing film removal process of step ST7, can be used. The preprocessing module and the graphene-containing film removal module may be implemented by a module equipped with a plasma generation mechanism having the same configuration as the hydrogen-containing plasma processing module 300. In addition, the hydrogen-containing plasma processing module 300 may be configured to have a function of at least one of these modules.

### Experimental Example

Next, an experimental example will be described.

Here, as a film formation inhibitor that inhibits formation of a target film on a Ru film, a graphene-containing film was formed, and effectiveness thereof was verified.

A SiO₂ film was used as the target film. Film formation inhibition ability (blocking ability) was evaluated by a contact angle of a film surface. As the contact angle increases, activity of the surface is reduced and the film formation inhibition ability (blocking ability) increases.

The graphene-containing film was formed using a module configured as the microwave plasma processing apparatus illustrated in FIGS. 8 to 10, C₂H₄ gas was used as a carbon-containing gas, a substrate temperature was set to 400 degrees C., and a film thickness was set to about 2 nm and about 4 nm (Samples 1 and 2). In addition, hydrogen-containing plasma processing was performed on the graphene film having a film thickness of 4 nm (Sample 3). The hydrogen-containing plasma processing was performed using the module of FIGS. 11, and H₂ gas and Ar gas were supplied under conditions of a substrate temperature: 150 degrees C., a microwave power: 200 W, and a time: 10 seconds. In addition, for comparison, after forming the graphene film having the thickness of 4 nm, a H₂ gas flow was performed at 150 degrees C. without using plasma (Sample 4).

With respect to Samples 1 to 4, a film formation flow of a SiO₂ film, which is a target film, was performed. The film formation flow was performed by supplying TMA gas and then supplying silanol gas.

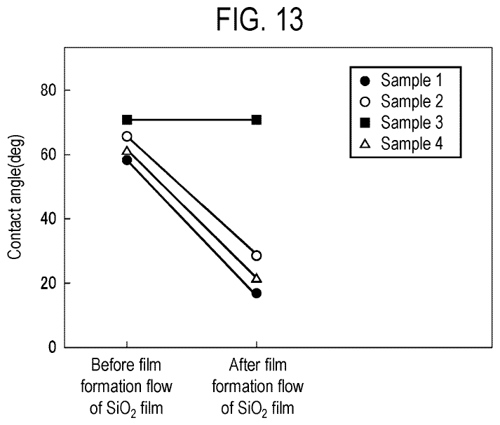

With respect to Samples 1 to 4, contact angles of the surfaces before and after the film formation flow of the SiO₂ film were measured. The results are illustrated in FIG. 13. As illustrated in FIG. 13, before the film formation flow of the SiO₂ film, the contact angles in all of Samples 1 to 4 were relatively high values of about 60 to 70 degrees, the contact angles increased though slightly as the film thickness increased, and the contact angles tended to increase by the hydrogen-containing plasma processing. On the other hand, after the film formation flow of the SiO₂ film, in Samples 1 and 2 in which the graphene-containing films were just formed and in Sample 4 in which the H₂ gas flow was performed, the contact angles decreased to about 30 degrees or less. In contrast, in Sample 3 in which the hydrogen-containing plasma processing was performed after the graphene-containing film was formed, the contact angle was maintained at 60 degrees or more even after the film formation flow of the SiO₂ film, and it was confirmed that the film formation inhibition effect of the SiO₂ film is high.

### Other Applications

Although the embodiments have been described above, it should be understood that the embodiments disclosed herein are exemplary in all aspects and are not restrictive. The above-described embodiments may be omitted, replaced, or modified in various forms without departing from the scope and spirit of the appended claims.

For example, the above-described embodiments have been described by taking as an example the substrate in which the second film is embedded in the recess formed in the first film, but the arrangement of the first film and the second film is not limited thereto. In addition, in the substrate having the first film and the second film different from the first film, materials of the first film and the second film do not matter as long as the target film is formed on the first surface of the first film and the graphene-containing film is selectively formed on the second surface of the second film.

In addition, in the above-described embodiments, the semiconductor wafer is used as the substrate, but the substrate is not limited thereto and another substrate such as a glass substrate or a ceramic substrate may be used.

The present disclosure provides a film forming method and a film forming apparatus capable of selectively forming a target film on a desired region of a substrate with high precision while suppressing damage.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method, comprising:
preparing a substrate including a first film having a first surface and a second film having a second surface, the second film being different from the first film;
selectively forming a graphene-containing film on the second surface;
performing hydrogen-containing plasma processing on the substrate after forming the graphene-containing film; and
selectively forming a target film on the first surface.

2. The film forming method of claim 1, wherein the first film is an insulating film and the second film is a conductive film.

3. The film forming method of claim 2, wherein the first film is at least one selected from the group consisting of a SiO₂ film, a SiN film, a SiOC film, a SiON film, and a SiOCN film.

4. The film forming method of claim 2, wherein the second film is at least one selected from the group consisting of a Cu film, a Co film, a Ru film, a W film, and a Mo film.

5. The film forming method of claim 1, wherein the target film is at least one selected from the group consisting of a SiO₂ film, an Al₂O₃ film, a SiN film, a ZrO₂ film, and a HfO₂ film.

6. The film forming method of claim 5, wherein when the target film is the SiO₂ film, the selectively forming the target film includes coating the substrate with a metal-containing catalyst layer by exposing the substrate to a metal-containing gas, and exposing the substrate to a silanol-containing processing gas after coating the substrate.

7. The film forming method of claim 1, wherein the graphene-containing film is formed by plasma chemical vapor deposition (CVD) or plasma atomic layer deposition (ALD).

8. The film forming method of claim 7, wherein the plasma CVD or the plasma ALD is performed using microwave plasma.

9. The film forming method of claim 7, wherein a temperature when forming the graphene-containing film is 250 to 450 degrees C.

10. The film forming method of claim 9, wherein the temperature when forming the graphene-containing film is 400 to 450 degrees C.

11. The film forming method of claim 7, wherein a film thickness of the graphene-containing film is 0.5 to 10 nm.

12. The film forming method of claim 11, wherein the film thickness of the graphene-containing film is 4 to 6 nm.

13. The film forming method of claim 1, wherein the hydrogen-containing plasma processing is a process of modifying the graphene-containing film.

14. The film forming method of claim 13, wherein the hydrogen-containing plasma processing uses H₂ gas as a hydrogen-containing gas.

15. The film forming method of claim 13, wherein the hydrogen-containing plasma processing is performed by setting a temperature to be in a range of 100 to 400 degrees C., setting a power to be in a range of 50 to 3,000 W, and setting a time to be in a range of 1 to 60 seconds.

16. The film forming method of claim 1, further comprising removing an excess portion of the target film by etching.

17. The film forming method of claim 16, wherein the substrate has a barrier film disposed between the first film and the second film, and a protruding portion of the target film is formed on a surface of the barrier film, and
wherein the removing the excess portion of the target film by etching includes removing the protruding portion as the excess portion.

18. The film forming method of claim 1, further comprising removing the graphene-containing film after forming the target film.

19. The film forming method of claim 1, wherein a native oxide film is formed on the second surface of the substrate, and
wherein the film forming method further comprises performing preprocessing of removing the native oxide film before forming the graphene-containing film.

20. A film forming apparatus, comprising:
a graphene-containing film formation module configured to form a graphene-containing film;
a hydrogen-containing plasma processing module configured to perform hydrogen-containing plasma processing;
a target film formation module configured to form a target film; and
a controller,
wherein the controller:
controls the graphene-containing film formation module to selectively form the graphene-containing film on a second surface of a substrate, the substrate including a first film having a first surface and a second film having the second surface, and the second film being different from the first film;
controls the hydrogen-containing plasma processing module to perform the hydrogen-containing plasma processing on the substrate after forming the graphene-containing film; and
controls the target film formation module to selectively form the target film on the first surface.
